(19) United States
(12) Patent Application Publication
(10) Pub. No.: US 2026/0202103 A1
(43) Pub. Date: Jul. 16, 2026

(54) ADIABATIC THERMAL REGULATOR

(71) Applicant: POLYTECH FORGE LLC, Port Charlotte, FL (US)

(72) Inventor: Jacob FRIEND, Brattleboro, VT (US)

(73) Assignee: POLYTECH FORGE LLC, Port Charlotte, FL (US)

(21) Appl. No.: 19/450,149

(22) Filed: Jan. 15, 2026

Related U.S. Application Data
(60) Provisional application No. 63/746,246, filed on Jan. 16, 2025.
(60) Provisional application No. 63/746,248, filed on Jan. 16, 2025.

(51) Int. Cl. F25B 9/14; G06F 30/18

(52) U.S. Cl. CPC F25B 9/14; G06F 30/18

(57) ABSTRACT

An adiabatic thermal regulator utilizing principles of adiabatic expansion and compression. The regulator can include a body having an internal passageway in communication with the exterior at both ends thereof, and at least one stage defined along a length of the passageway. The stage can include at least one expansion chamber, at least one upstream channel portion, and at least one downstream channel portion, the channel portions having smaller diameters than the expansion chamber. The stage is configured to cause a gas flowing therethrough to undergo compression and expansion as the gas flows through the stage, such that a temperature of the gas is modified via adiabatic or near-adiabatic processes. A plurality of stages may be provided. A plurality of expansion chambers may be provided at each stage. The total expansion chamber volume of a stage may be greater than the total expansion chamber volume of a downstream stage.

### CROSS-REFERENCE TO RELATED APPLICATIONS

This application claims priority to U.S. Provisional Application 63/746,246, filed Jan. 16, 2025, and to U.S. Provisional Application 63/746,248, filed Jan. 16, 2025, the entire contents of each of which are hereby incorporated by reference.

### BACKGROUND

Existing technologies for gas and fluid temperature regulation, such as vortex tubes and heat exchangers, have shortcomings. Vortex tubes use rapid gas expansion to achieve temperature differentiation but lack fine temperature control. Heat exchangers, on the other hand, transfer heat between fluids but do not rely on rapid internal temperature regulation. Traditional heaters, in turn, rely on burning fuel or electrical resistance to provide heat. A solution that uses less energy compared to traditional heating methods, provides high-precision control over final air temperatures for different applications, and can be adapted to different industries with ease is therefore desired.

### SUMMARY

According to at least one exemplary embodiment, an adiabatic thermal is provided. The regulator can include a body having an internal passageway in communication with the exterior at both ends thereof, and at least one stage defined along a length of the passageway. The stage can include at least one expansion chamber, at least one upstream channel portion, and at least one downstream channel portion, the channel portions having smaller diameters than the expansion chamber. The stage is configured to cause a gas flowing therethrough to undergo compression and expansion as the gas flows through the stage, such that a temperature of the gas is modified via adiabatic or near-adiabatic processes. A plurality of expansion chambers may be provided at the stage.

According to another exemplary embodiment, a plurality of stages may be provided. A plurality of expansion chambers may be provided at each stage. The total expansion chamber volume of a stage may be greater than the total expansion chamber volume of a downstream stage. The upstream channel portion of each stage may be in communication with a downstream channel portion of an upstream stage or with a portion of the passageway in communication with the upstream end of the body. A downstream channel portion of each stage may be in communication with an upstream channel portion of a downstream stage or with a portion of the passageway in communication with the downstream end of the body.

According to another exemplary embodiment, a plurality of non-intersecting internal passageways may be provided. Each passageway may be in communication with at least one environment external to the body at the upstream end and at the downstream end and may include at least one stage.

According to another exemplary embodiment, a method of regulating a temperature of a gas using an adiabatic thermal regulator is disclosed. The method can include introducing gas into the passageway at an upstream end of the body, flowing the gas through the stage, modifying a temperature of the gas via adiabatic or near-adiabatic compression and expansion as it flows through the stage, and receiving the gas from the passageway at a downstream end of the body. The step of flowing the gas through the stage can include compressing the gas through the channel portion positioned upstream of the expansion chamber, expanding the gas by flowing the gas into the expansion chamber, and flowing the gas through the channel portion positioned downstream of the expansion chamber. The step of flowing the gas through the channel portion positioned downstream of the expansion chamber can include compressing the gas.

According to another exemplary embodiment, a method of designing an adiabatic thermal regulator is disclosed. The method can include selecting a desired thermal effect to be imparted to a gas flowing through the passageway, determining a number of stages to be defined along the passageway based on the desired thermal effect, and determining a desired mass flow rate of the gas. For each stage, the method can include selecting a volume of the expansion chamber, selecting geometries of channel portions positioned upstream and downstream of the expansion chamber relative to the selected volume of the expansion chamber, and configuring the expansion chamber and channel portions such that gas flowing through the stage undergoes compression and expansion under adiabatic or near-adiabatic conditions.

### BRIEF DESCRIPTION OF THE FIGURES

Advantages of embodiments of the present invention will be apparent from the following detailed description of the exemplary embodiments. The following detailed description should be considered in conjunction with the accompanying figures in which:

FIG. 1 is an isometric view of an exemplary embodiment of a thermal regulator, showing internal structure.

FIG. 2 is a front view of the exemplary embodiment of a thermal regulator, showing internal structure.

FIG. 3 is a cross-sectional view of the exemplary embodiment of a thermal regulator, along line A-A of FIG. 2.

FIG. 4 is a side view of the exemplary embodiment of a thermal regulator, showing internal structure.

FIG. 5 is a cross-sectional view of the exemplary embodiment of a thermal regulator, along line B-B of FIG. 4.

FIG. 6 is a cross-sectional view of the exemplary embodiment of a thermal regulator, along line C-C of FIG. 2.

FIG. 7 is a cross-sectional view of the exemplary embodiment of a thermal regulator, along line D-D of FIG. 2.

FIG. 8 is a cross-sectional view of the exemplary embodiment of a thermal regulator, along line E-E of FIG. 2.

FIG. 9 is a top view of the exemplary embodiment of a thermal regulator.

FIG. 10 is a bottom view of the exemplary embodiment of a thermal regulator.

FIG. 11 is a front view of another exemplary embodiment of a thermal regulator, showing internal structure.

### DETAILED DESCRIPTION

Aspects of the invention are disclosed in the following description and related drawings directed to specific embodiments of the invention. Those skilled in the art will recognize that alternate embodiments may be devised without departing from the spirit or the scope of the claims. Additionally, well-known elements of exemplary embodiments of the invention will not be described in detail or will be omitted so as not to obscure the relevant details of the invention. Further, to facilitate an understanding of the description discussion of several terms used herein follows.

As used herein, the word “exemplary” means “serving as an example, instance or illustration.” The embodiments described herein are not limiting, but rather are exemplary only. It should be understood that the described embodiment are not necessarily to be construed as preferred or advantageous over other embodiments. Moreover, the terms “embodiments of the invention”, “embodiments” or “invention” do not require that all embodiments of the invention include the discussed feature, advantage or mode of operation. Furthermore, as used herein, the terms “upstream” and “downstream” should be understood as being discussed with respect to the direction of the airflow path.

According to at least one exemplary embodiment, a thermal regulator device is disclosed. The thermal regulator device may utilize the principles of adiabatic expansion and compression, combined with the use of converging and diverging nozzles, to rapidly heat compressed gas. The thermal regulator device may include a sequence of spherical chambers and channels that leverage fluid dynamics to achieve efficient thermal regulation. By leveraging a combination of converging-diverging nozzles and spherical chambers, the thermal regulator device can provide precise temperature control and efficiency gains over existing technologies.

The thermal regulator device may operate based on adiabatic processes wherein gas is compressed and expanded through a series of chambers and channels between the chambers. The chambers may be substantially spherical, while the channels may be cylindrical, nozzle-like, or venturi-like. In an adiabatic compression, the temperature of the gas rises without heat exchange, while adiabatic expansion lowers the temperature of the gas. The thermal regulator device can repeatedly subject a gas to these processes to control a final temperature of the gas. In the thermal regulator device, compressed gas may be forced through structures that increase and decrease the velocity of the gas in quick cycles. As the gas is subjected to these cycles, the gas may heat up without provision of an external heat source. By modifying the shape and size of the chambers, the temperature of the gas exiting the device can be precisely controlled.

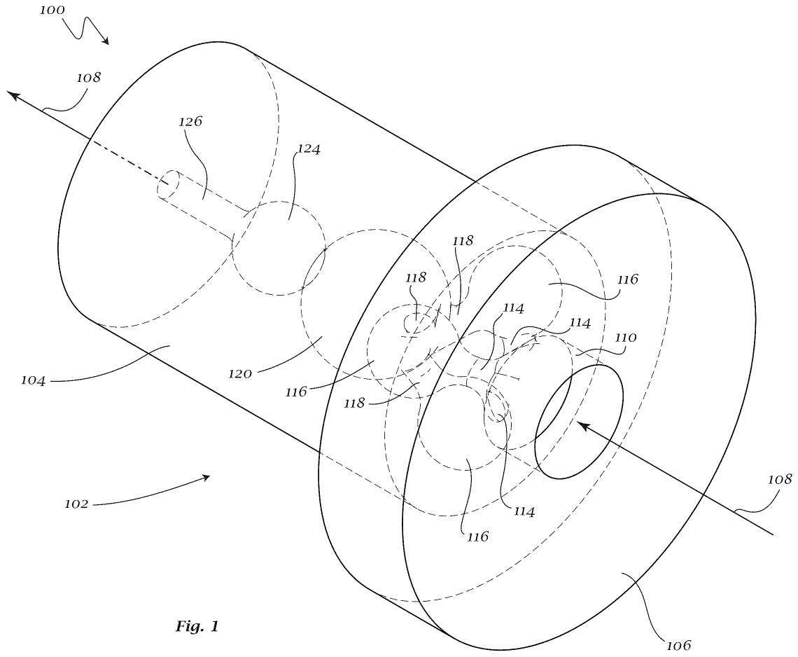

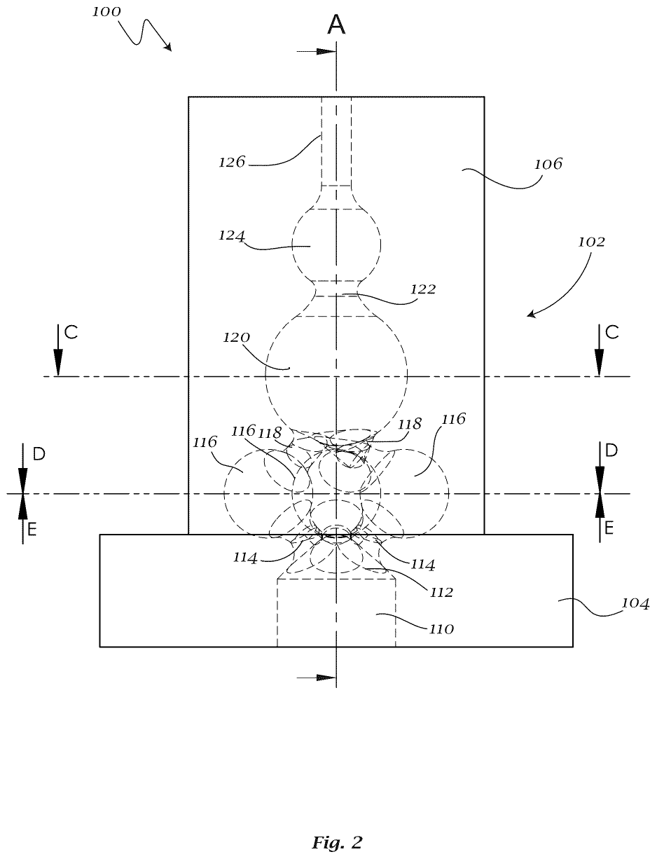

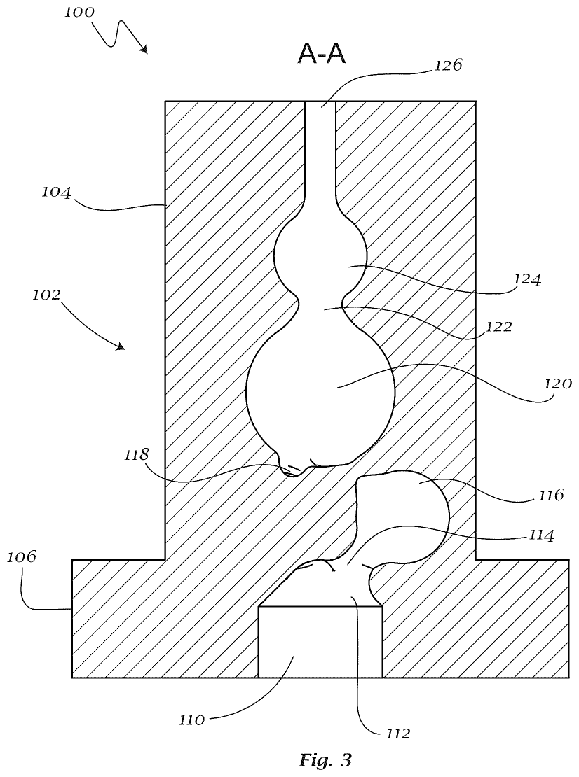

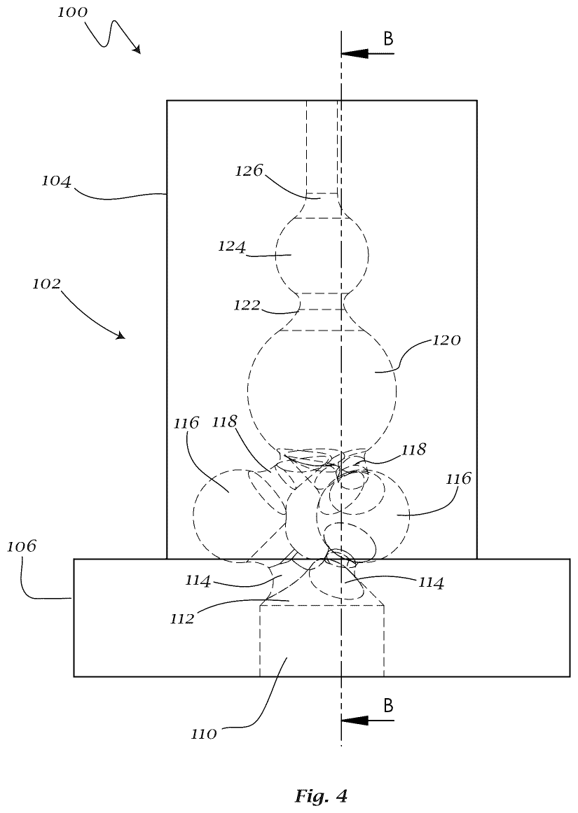

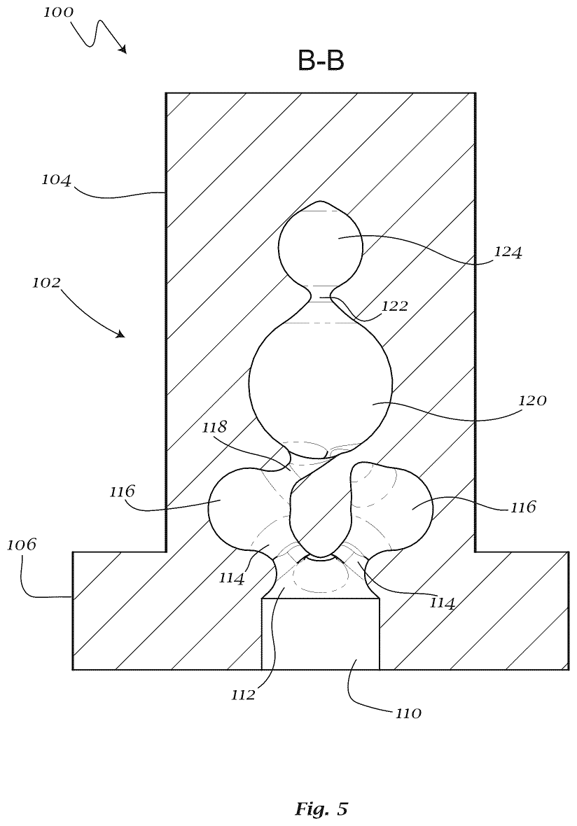

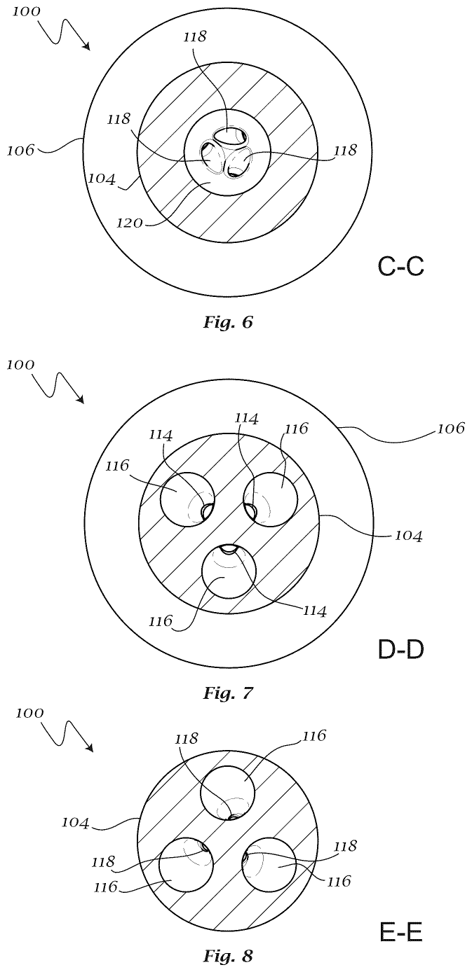

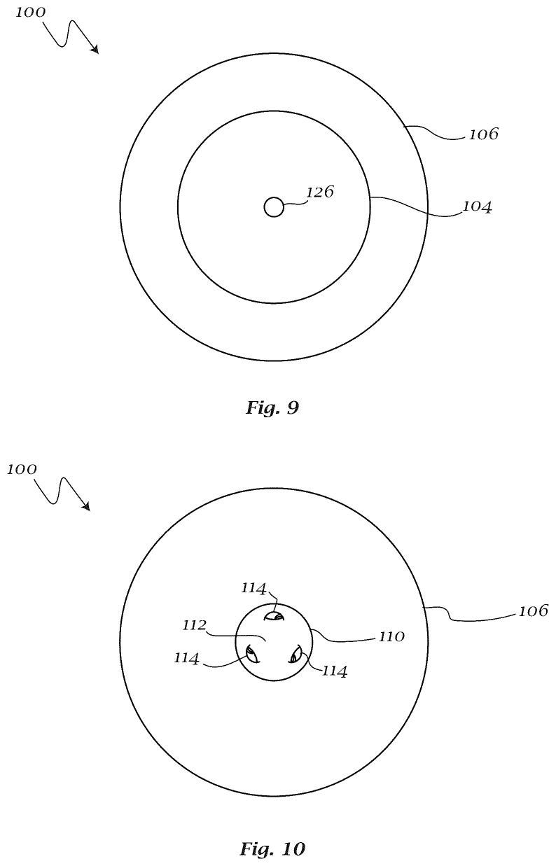

According to at least one exemplary embodiment, and with reference to FIGS. 1-8, a thermal regulator 100 is disclosed. Thermal regulator 100 can include a body 102, which can include a cylindrical portion 104 and a flange portion 106 disposed coaxially therewith. A passageway may extend from a upstream end of body 102 to a downstream end of body 102 that is opposite the upstream end. The passageway may be substantially coaxial with the longitudinal axis of body 102. Air may pass through the passageway along airflow path 108. The passageway may have a plurality of chambers and a plurality of channels disposed along the length of the passageway, which will be discussed in the direction of airflow path 108.

Disposed at the upstream end of body 102, at flange portion 106, and open to the exterior may be entry plenum 110. Entry plenum 110 may be cylindrical and have a constant diameter along a first portion of its length. Along a second, downstream portion of the length of plenum 110 may be a converging conical portion 112, having a diameter reducing along the direction of airflow path 108.

Downstream of and in communication with conical portion 112 may be one or more of first channels 114, connecting conical portion 112 to one or more first expansion chambers 116 downstream of conical portion 112. First channels 114 may have smaller diameters than plenum 110 and first expansion chambers 116, and may have a substantially hourglass shape. As seen in the direction of the airflow, each first channel 114 may include a converging portion proximate conical portion 112 and a diverging portion proximate the respective first expansion chamber 116. A tubular portion may be provided between the converging portion and the diverging portion.

First expansion chambers 116 may have a substantially spherical shape, and may be disposed radially symmetrically about the longitudinal axis of body 102. In the exemplary embodiment, three first expansion chambers 116 are shown. However, any quantity of first expansion chambers 116 that enable thermal regulator 100 to function as described herein may be contemplated and provided as desired.

In communication with first expansion chambers 116 may be one or more of second channels 118, connecting first expansion chambers 116 to a second expansion chamber 120 downstream of first expansion chambers 116. Second passages 118 may have smaller diameters than first expansion chambers 116 and second expansion chamber 120, and may have a substantially hourglass shape. As seen in the direction of the airflow, each second channel 118 may include a converging portion proximate the respective first expansion chamber 116, and a diverging portion proximate the second expansion chamber 120. A tubular portion may be provided between the converging portion and the diverging portion.

Second expansion chamber 120 may have a substantially spherical shape with a diameter greater than the diameter of a first expansion chamber 116, and may be disposed coaxially to the longitudinal axis of body 102. Second expansion chamber 120 may be in communication with a third expansion chamber 124, downstream of second expansion chamber 120, via a third channel 122. Third channel 122 may have a substantially hourglass shape and a diameter smaller than third expansion chamber 124. As seen in the direction of the airflow, third channel 118 may include a converging portion proximate second expansion chamber 120, and a diverging portion proximate third expansion chamber 124. A tubular portion may be provided between the converging portion and the diverging portion. Second expansion chamber 120, third channel 122, and third expansion chamber 124 may be disposed coaxially to each other.

Third expansion chamber 124 may have a substantially spherical shape and a diameter smaller than the diameter of second expansion chamber 120. In communication with third expansion chamber 124 may be an exit channel 126. Exit channel 126 may have a substantially cylindrical shape and a diameter smaller than the diameter of third expansion chamber 124. Exit channel 126 may include a converging portion proximate third expansion chamber 124 and a cylindrical portion extending downstream from the converging portion and in communication with the exterior. Exit channel 126 may be disposed coaxially to third expansion chamber 124, third channel 122, second expansion chamber 120, and plenum 110.

The external dimensions of the exemplary embodiment of thermal regulator 100 may be as follows. Body 102 may have a height of approximately 9.3 mm. Cylindrical portion 104 may have a height of approximately 7.4 mm and a diameter of approximately 5.0 mm. Flange portion 106 may have a height of approximately 1.9 mm and a diameter of approximately 8.0 mm. However, these dimensions are merely intended to provide a general sense of scale and should be understood to be exemplary and non-limiting; the dimensions may be adjusted as desired for the particular application of the thermal regulator. Additionally, the dimensioning and layout of the internal chambers, passageways, and channels of the thermal regulator is discussed in detail further below.

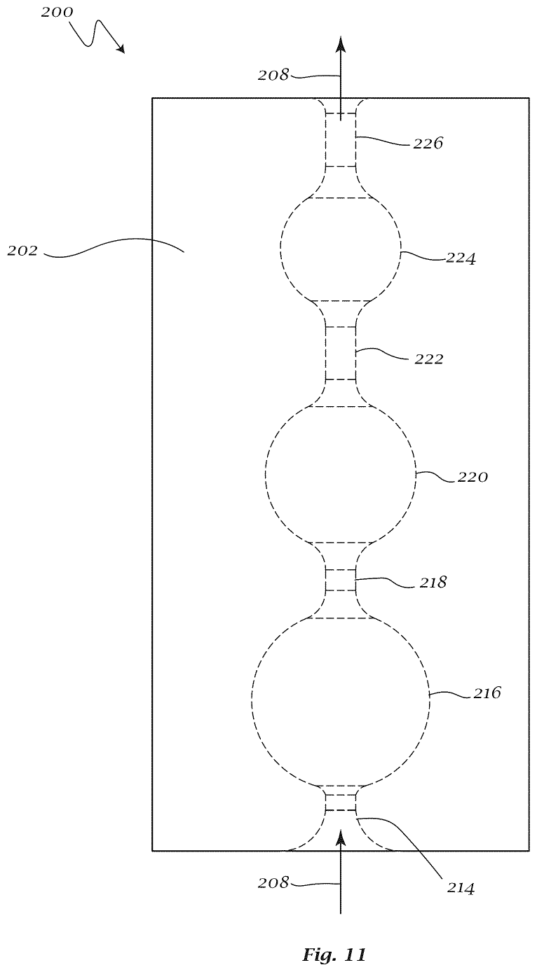

FIG. 11 shows another exemplary embodiment of a thermal regulator 200. Similar features are identified by similar reference numerals, but with a leading digit of 2.

Thermal regulator 200 can include a cylindrical body 202. A passageway may extend from a upstream end of body 202 to a downstream end of body 202 that is opposite the upstream end. The passageway may be coaxial with the longitudinal axis of body 202. Air may pass through the passageway along airflow path 208.

The passageway may have a plurality of chambers and a plurality of channels disposed along the length of the passageway, which will be discussed in the direction of airflow path 208. Disposed at the upstream end of body 202 and open to the exterior may be first (entry) channel 214. First channel 214 may extend from the upstream end of body 202 to first expansion chamber 216, downstream of the upstream end. As seen in the direction of the airflow, first channel 214 may include a converging portion proximate upstream end of body 202, and a diverging portion proximate first expansion chamber 216. A tubular portion may be provided between the converging portion and the diverging portion.

First expansion chamber 216 may have a substantially spherical shape, and may be disposed coaxially to first channel 214 and to the longitudinal axis of body 202. In communication with first expansion chamber 216 may be second channel 218, connecting first expansion chamber 216 to second expansion chamber 220 downstream of first expansion chamber 216. As seen in the direction of the airflow, second channel 218 may include a converging portion proximate first expansion chamber 216, and a diverging portion proximate second expansion chamber 220. A tubular portion may be provided between the converging portion and the diverging portion.

Second expansion chamber 220 may have a substantially spherical shape with a diameter less than the diameter of first expansion chamber 216, and may be disposed coaxially to the longitudinal axis of body 202. In communication with second expansion chamber 220 may be third channel 222, connecting second expansion chamber 220 to third expansion chamber 224 downstream of second expansion chamber 220. As seen in the direction of the airflow, third channel 222 may include a converging portion proximate second expansion chamber 220, and a diverging portion proximate second expansion chamber 224. A tubular portion may be provided between the converging portion and the diverging portion.

Third expansion chamber 224 may have a substantially spherical shape with a diameter less than the diameter of second expansion chamber 220, and may be disposed coaxially to the longitudinal axis of body 202. Downstream of and in communication with third expansion chamber 224 may be an exit channel 226. Exit channel 226 may have a substantially cylindrical shape and a diameter smaller than the diameter of third expansion chamber 224. Exit channel 226 may include a converging portion proximate third expansion chamber 224 and a diverging portion proximate to and in communication with the exterior. A tubular portion may be provided between the converging portion and the diverging portion. Exit channel 226 may be disposed coaxially to third expansion chamber 224, third channel 222, second expansion chamber 220, second channel 218, first expansion chamber 216, and first (entry) channel 214.

Embodiments of the thermal regulator may operate through a series of rapid adiabatic expansions and compressions, using specifically designed converging and diverging nozzles (i.e., the converging and diverging portions of the channels described above, the converging and diverging portions having a varying cross-sectional area along the length thereof), connected by spherical chambers. The nozzles may converge and diverge linearly or along a curvature. The flow of compressed gas is directed through these nozzles, where each stage performs a distinct role in the heating process. In a first stage, gas may enter the system under high pressure and passes through the first converging nozzles. The reduction in nozzle diameter increases the velocity of the gas, lowering the pressure of the gas and expanding the gas. In a second stage, the gas may then enter a diverging nozzle, followed by a spherical chamber, where the gas may undergo controlled expansion. At this point, the temperature of the gas may begin to rise due to the energy conservation principles in the chamber, which also acts as a buffer for downstream stages. In a third stage, the gas may once again be compressed by the next converging nozzle as as the gas exits the chamber and enters the next stage of heating. The alternation between converging and diverging nozzles ensures the gas repeatedly undergoes adiabatic heating. As the gas completes its path through multiple chambers, the gas may exit the thermal regulator with the desired final temperature.

In addition to the exemplary embodiments disclosed herein, it should be appreciated that variations in the design of the internal structures are possible, including but not limited to: variation in number of chambers, variation in position of chambers, variation in shape of chambers, variation in length of connecting points; variation in the channels and venturi sections such as: number of channels, as well as the size, shape, diameter and directional orientation of the channels, and variation in the quantity of utilities per device (i.e., multiple flow paths in the same device, significant increases in the number of chambers, and significant increases in the flow rate of the device).

Such variations may be provided and selected as desired so as to control temperature and flow rate. As a non-limiting example, variations may be provided as to the size of the chambers, the quantity of the chambers, and the ratio of chamber size to the channels leading into and out of each chamber. For example, multiple channels can feed a single chamber, allowing for higher flow rates and flow path control strategies such as, for example, inducing cyclonic flow. As a further non-limiting example, multiple passageways could be provided in an embodiment of the adiabatic thermal regulator. Such passageways may run in parallel or in an otherwise non-intersecting manner with respect to each other, thereby allowing for extreme-flow demand systems to experience the same level of benefit as a single flow path system. Providing such multiple passageways in this manner may facilitate scaling of the system while maintaining the microscale functions of adiabatic heating via expansion and compression.

Additionally, variation in channel design may be used to control flow volume and characteristics, for example, to control how smoothly and aggressively flow occurs between chambers, so as to facilitate controlling vorticing, turbulence, and chamber timing. For example, providing channels with an excessively large diameter may cause the associated chamber to fill and empty too rapidly for adiabatic heating to occur. Conversely, providing channels with an excessively small diameter may restrict flow such that expansion and compression occurs too gradually to induce adiabatic heating and may also prevent optimal function of the overall system, thereby eliminating any gains that may be introduced by usage of thermal regulation.

It should be appreciated that linear flow passageways, similar to the exemplary embodiment of thermal regulator 200, may be advantageous for use with gases that undergo sublimation upon transition from compressed liquid-state storage to a gaseous flowing system, and may aid CO₂ interaction with thermal regulation properties. If excess pressurization is provided, such gases may revert to the liquid phase, thereby negating adiabatic heating properties. It has therefore been found that linear expansion and less complicated flow passageways are advantageous for maintaining heating properties for media that undergo sublimation during decompression and liquefaction during compression, as they reduce the likelihood of or prevent liquefaction during the compression stages. In contrast, providing more complex internal passageways, similar to the exemplary embodiment of thermal regulator 100, may be advantageous for use with gases that remain gaseous at higher-pressure ranges, such as, for example, nitrogen and helium.

Embodiments of the adiabatic thermal regulator may be designed and proportioned using a set of geometric relationships referred to herein as Priest ratio design principles. The Priest ratio design principles provide first-pass geometric sizing relationships that relate internal chamber volumes and connecting channel geometries to desired gas-flow dynamics and thermal output, without reliance on moving, mechanical compression elements. The Priest ratio design principles are provided such that the channel and chamber geometries directly relate to the desired mass/volumetric flow rate and the desired heating/cooling power (i.e., thermal output). Furthermore, the Priest ratio design principles may be adapted for standard compression gases, (i.e., gases that remain gaseous at high pressures such as nitrogen, helium, air, etc.) and phase-change and near-saturation gases (i.e., gases that undergo sublimation during decompression and liquefaction during compression, such as carbon dioxide, propane, etc.)

In at least one exemplary embodiment, the thermal regulator may include a plurality of stages, each stage comprising at least one expansion chamber and at least one feeding channel in fluid communication therewith. For a given stage i, a Priest ratio Φᵢ may be defined as a geometric relationship between the chamber volume and the effective geometry of the associated channel.

In one exemplary formulation, the Priest ratio Φᵢ may be expressed as:

$${Φ}_{i} = \frac{{V}_{i}}{{A}_{t , i} \cdot {L}_{eff , i}} \qquad ( 1 )$$

where Vᵢ is the volume of the chamber, A_{t,i} is a minimum (throat) cross-sectional area of the feeding channel, and L_{eff,i} is an effective channel length that may include the physical channel length and end corrections. Other equivalent geometric formulations may be used without departing from the scope of the invention.

The Priest ratio may be selected so as to correspond to a characteristic dynamic response of the gas flowing through the thermal regulator. The characteristic response may be represented by a design frequency f* associated with the rate at which gas is intended to charge and discharge each chamber without excessive losses or instability. For single-phase gases, such as air, nitrogen, or helium, the characteristic propagation velocity of the gas may be approximated by the local speed of sound c, where:

$$c = \sqrt{γ RT} \qquad ( 2 )$$

In such embodiments, the Priest ratio may be selected according to the relationship:

$$Φ = {( \frac{c}{2 π {f}^{*}} )}^{2} \qquad ( 3 )$$

Accordingly, the chamber volume Vᵢ may be expressed in terms of channel geometry and the selected response frequency as:

$${V}_{i} = {( \frac{c}{2 π {f}^{*}} )}^{2} \cdot {A}_{t , i} \cdot {L}_{eff , i} \qquad ( 4 )$$

For gases operating near saturation or exhibiting phase-change behavior, such as carbon dioxide or certain refrigerants, the same geometric structure may be employed, but the characteristic propagation velocity may be replaced with an effective compressibility velocity c_{eff}. In one exemplary embodiment, the effective velocity may be expressed as:

$${c}_{eff} = \sqrt{\frac{{K}_{eff}}{ρ}} \qquad ( 5 )$$

where

$${K}_{eff} = ( \frac{\partial P}{\partial ρ} ) s .$$

In such embodiments, the Priest ratio may be expressed as:

$$Φ = {( \frac{{c}_{eff}}{2 π {f}^{*}} )}^{2} \qquad ( 6 )$$

and the corresponding chamber volume may be expressed as:

$${V}_{i} = {( \frac{{c}_{eff}}{2 π {f}^{*}} )}^{2} \cdot {A}_{t , i} \cdot {L}_{eff , i} \qquad ( 7 )$$

Conservative selection of c_{eff} may improve operational stability in regimes where real-gas effects or phase transition phenomena may occur.

The Priest ratio design principles may then be combined with conventional compressible-flow relationships to relate internal geometry to a desired mass flow rate. For example, the minimum cross-sectional throat area Aₜ of a channel may be selected to support a target mass flow rate under choked-flow conditions. In one exemplary formulation, the choked-flow mass flow rate m through a throat, for a single-phase, ideal-gas first pass may be approximated as:

$$\dot{m} = {C}_{d} \cdot {A}_{t} \cdot {P}_{0} \cdot \sqrt{\frac{γ}{R {T}_{0}}} \cdot {( \frac{2}{γ} + 1 )}^{\frac{γ + 1}{2 ( γ - 1 )}} \qquad ( 8 )$$

where C_{d} is a discharge coefficient (which may be 0.70-0.95 at typical first-pass), and P₀ and T₀ are upstream stagnation pressure and temperature, respectively. Solving for the throat area yields:

$${A}_{t} = \frac{\dot{m}}{{C}_{d} \cdot {A}_{t} \cdot {P}_{0} \sqrt{\frac{γ}{R {τ}_{0}}} \cdot {( \frac{2}{γ} + 1 )}^{\frac{γ + 1}{2 ( γ - 1 )}}} \qquad ( 9 )$$

Once a channel area is selected to accommodate the desired mass flow, the corresponding chamber volume may be determined using the Priest ratio relationships described above.

Additionally, chamber volume may be constrained by a volumetric turnover relationship linking chamber volume directly to flow. A stage turnover factor ηᵥ, where (0<ηᵥ<1), may be defined to represent a volumetric turnover factor indicating the usable fraction of chamber volume exchanged per cycle. Then, the minimum chamber volume Vᵢ required to support the desired \dot{m} at a stage frequency f* is:

$${V}_{i} \geq \frac{\dot{m}}{{ρ}_{i} \cdot {η}_{v} \cdot {f}^{*}} \qquad ( 10 )$$

This inequality represents a practical sizing bridge, wherein higher required flow pushes volumes up, or requires higher f*.

According to at least one exemplary embodiment, the thermal regulator operates through repeated compression and expansion of gas as the gas flows through successive converging and diverging channels and expansion chambers. These processes may occur sufficiently rapidly that heat exchange with the surroundings is limited, such that the gas undergoes predominantly adiabatic or near-adiabatic transformations.

Thermal output may be expressed as a power \dot{Q} (W) associated with a mass flow undergoing a change in specific enthalpy:

$$\dot{Q} = \dot{m} \cdot Δ h \qquad ( 11 )$$

For single phase gases, the specific enthalpy change may be approximated as:

$$Δ h \approx {c}_{p} ( {T}_{o u t} - {T}_{i n} ) \qquad ( 12 )$$

where outlet temperature may be estimated using an isentropic relationship:

$${T}_{o u t} = {{T}_{i n} ( \frac{{P}_{2}}{{P}_{1}} )}^{\frac{γ - 1}{γ}} \qquad ( 13 )$$

Therefore, the required mass flow for a target \dot{Q} is:

$$\dot{m} = \frac{\dot{Q}}{{c}_{p} ( {T}_{o u t} - {T}_{i n} )} \qquad ( 14 )$$

For gases undergoing phase change, the enthalpy change may additionally include latent heat contributions, such that:

$$Δ h = {h}_{o u t} - {h}_{i n} \approx {c}_{p , eff} ( {T}_{o u t} - {T}_{i n} ) + x \cdot L \qquad ( 15 )$$

where x is the mass fraction undergoing phase change, and L is the relevant latent heat (i.e., vaporization or sublimation). Thus, the mass flow required for a target \dot{Q} dot is:

$$\dot{m} = \frac{\dot{Q}}{Δ h} \qquad ( 16 )$$

The Priest ratio design principles do not prescribe a specific temperature change. Rather, they may provide a geometric framework that enables the staged chamber-and-channel architecture to support the mass flow and dynamic response required for the desired enthalpy change to occur under selected operating conditions. In practice, the Priest ratio design principles may be used as an initial sizing methodology during design of an adiabatic thermal regulator. After a first-pass geometry is selected using the Priest ratio relationships, the design may be refined using real-gas property data, pressure-loss modeling, heat-transfer considerations, and empirical testing.

According to at least one exemplary embodiment, the adiabatic thermal regulator may be designed using a combined application of the Priest ratio design principles and conventional flow and energy relationships to relate desired thermal output directly to internal geometry. In such embodiments, the internal chambers and connecting channels may be proportioned so as to support a required mass flow rate while enabling a desired change in gas enthalpy through adiabatic or near-adiabatic compression and expansion.

In one exemplary design approach, the internal geometry of the thermal regulator may be selected by first determining a required thermal output and an associated outlet condition, such as an outlet temperature or pressure ratio. Based on the desired thermal output, a corresponding mass flow rate may be determined using an energy balance relationship in which thermal power is expressed as a product of mass flow and specific enthalpy change.

Once a target mass flow rate is identified, one or more channel cross-sectional areas may be selected to accommodate the mass flow under anticipated operating conditions, such as choked or near-choked flow. After channel geometry is established, chamber volumes associated with each stage may be determined using the Priest ratio relationships described above, such that the chambers are capable of exchanging gas at a desired dynamic response rate without excessive loss or instability.

In this manner, the Priest ratio design principles may provide a unified geometric framework that links desired thermal output and flow capacity to chamber and channel sizing, while allowing thermodynamic behavior to be evaluated separately based on selected operating conditions and gas properties.

According to at least one exemplary embodiment, a method of designing or configuring an adiabatic thermal regulator may include applying the Priest ratio design principles in combination with flow and energy relationships to relate a desired thermal output directly to internal geometry of the regulator.

The method may include determining a desired thermal output for the thermal regulator. The desired thermal output may correspond to a target heating power, cooling power, outlet temperature, temperature change, or pressure ratio associated with gas flowing through the thermal regulator.

The method may further include determining a required mass flow rate of gas based on the desired thermal output. The mass flow rate may be determined using an energy balance relationship in which thermal power is expressed as a product of mass flow and a specific enthalpy change of the gas. The specific enthalpy change may be estimated based on adiabatic or near-adiabatic compression and expansion of the gas, and may further account for real-gas effects or phase-change behavior where applicable.

The method may further include selecting at least one channel geometry to accommodate the determined mass flow rate. In one exemplary embodiment, this may include selecting a minimum cross-sectional area of a channel or throat region such that the required mass flow rate may be supported under anticipated operating conditions, such as choked or near-choked flow. The method may further include selecting a characteristic response frequency associated with operation of the thermal regulator. The characteristic response frequency may represent a rate at which gas is intended to charge and discharge one or more chambers of the thermal regulator without excessive pressure loss, flow instability, or undesired backflow.

The method may further include determining one or more chamber volumes using the Priest ratio design principles described above. In such embodiments, the chamber volumes may be selected based on the selected channel geometry, effective channel length, characteristic response frequency, and a characteristic gas propagation velocity corresponding to the gas and operating regime. This step may include selecting different chamber volumes for different stages of the thermal regulator. The method may further include configuring a plurality of chambers and connecting channels in a staged arrangement such that gas undergoes repeated compression and expansion as it flows through the thermal regulator. In such embodiments, the staged arrangement may include converging and diverging channel portions and expansion chambers arranged to promote adiabatic or near-adiabatic transformations of the gas.

According to at least one exemplary embodiment, the Priest ratio design principles may be used as a first-pass sizing methodology during development of an adiabatic thermal regulator. Certain parameters may be treated as adjustable design factors during this process, including, but not limited to, discharge coefficients associated with channels, volumetric turnover factors associated with chambers, and characteristic response frequencies selected for stable operation.

In embodiments intended to produce net thermal output to an external environment, such as through a heat exchanger or downstream thermal interface, the enthalpy change used in determining mass flow may include heat transferred external to the regulator body. In other embodiments, where the objective is to raise or lower the temperature of the gas itself, the enthalpy change may correspond primarily to internal compression and expansion processes occurring within the regulator.

For gases operating near saturation or in regimes where real-gas effects may become significant, conservative selection of effective gas properties may be employed during initial sizing to improve stability and reduce sensitivity to phase-transition phenomena. After an initial geometry is established using the Priest ratio design principles, the design may be refined using more detailed analyses, including real-gas property data, pressure-loss modeling, heat-transfer analysis, and empirical testing.

The Priest ratio design principles are intended to be broadly applicable across a wide range of adiabatic thermal regulator configurations, including variations in the number of stages, chamber shapes, channel geometries, and flow paths, without departing from the scope of the invention.

Due to the complex microfluidic pathways required for the system's optimal function, manufacturing of the embodiments disclosed herein may necessitate advanced manufacturing techniques, including 3D printing (additive manufacturing), computer numerical control (CNC) machining, Electrical Discharge Machining (EDM) or microfabrication.

Additive manufacturing methods may be suited for producing intricate designs such as the internal chambers and nozzle pathways. Various methods exist; for example, elective laser sintering (SLS) or direct metal laser sintering (DMLS) can be employed to build the microfluidic pathways layer by layer, ensuring precision in the nozzle diameters and chamber configurations. Any form of additive manufacturing may be capable of producing the desired parts. For parts that don't require micro-scale precision, CNC machining may be a potential option. Larger components, like external casings or support structures, can be produced using traditional subtractive manufacturing techniques, while maintaining the integrity of the smaller, intricate parts produced by other methods. For producing extremely small and precise nozzles and pathways, microfabrication techniques such as photolithography and etching could be employed. These methods would allow for the creation of microfluidic systems where the pathways are on the order of micrometers, ideal for achieving the exact tolerances necessary.

Additionally, if the design cannot be produced as a single integrated unit, multiple small, individual components may be manufactured separately through standard production and manufacturing avenues such as, for example, machining. These components may be assembled using precise alignment techniques and secured in an air-tight or near-airtight manner to form the final assembly. While such assembly may require increased costs, and may result in larger part sizes with respect to the prior-discussed methods, it would allow for flexibility in material choice, such as using different metals or polymers for various sections, depending on the thermal or structural requirements. However, any manufacturing methods that enable the adiabatic thermal regulator to function as described herein may be contemplated and provided as desired.

The embodiments disclosed herein may be utilized in various industries, including HVAC systems, automotive, aerospace, and medical devices. In advanced heating, ventilation, and air conditioning systems, the embodiments may be used to efficiently heat or cool gases as part of a temperature control mechanism. In automotive applications, the embodiments may be used in turbocharging systems or exhaust heat recovery to control gas temperatures. In aerospace, the embodiments may be used in propulsion systems where managing compressed gases at varying temperatures is critical. In medical devices, the embodiments may be used to facilitate precision temperature regulation of respiratory gases in devices such as ventilators or in sterilization systems. Additionally, the embodiments disclosed herein may be used in a passive pressure amplification device, substantially as described in U.S. Provisional Patent Application 63/746,248, the entire contents of which are incorporated herein by reference.

The foregoing description and accompanying figures illustrate the principles, preferred embodiments and modes of operation of the invention. However, the invention should not be construed as being limited to the particular embodiments discussed above. Additional variations of the embodiments discussed above will be appreciated by those skilled in the art.

Therefore, the above-described embodiments should be regarded as illustrative rather than restrictive. Accordingly, it should be appreciated that variations to those embodiments can be made by those skilled in the art without departing from the scope of the invention as defined by the following claims.

What is claimed is:

1. An adiabatic thermal regulator, comprising:
a body having an upstream end, a downstream end, and an internal passageway extending therebetween, the internal passageway being in communication with at least one environment external to the body at the upstream end and at the downstream end;
at least one stage defined along a length of the passageway, the stage comprising:
at least one expansion chamber defined along a portion of the passageway;
at least one upstream channel portion in communication with the expansion chamber, having a diameter smaller than a diameter of the expansion chamber, and defined along a portion of the passageway upstream of the one expansion chamber; and
at least one downstream channel portion in communication with the expansion chamber, having a diameter smaller than the diameter of the expansion chamber, and defined along a portion of the passageway downstream of the expansion chamber;
wherein the stage is configured to cause a gas flowing therethrough to undergo compression and expansion as the gas flows through the stage, such that a temperature of the gas is modified via adiabatic or near-adiabatic processes.

2. The adiabatic thermal regulator of claim 1, wherein the expansion chamber has a substantially spherical geometry.

3. The adiabatic thermal regulator of claim 1, wherein the upstream channel portion includes at least one of a converging portion and a diverging portion.

4. The adiabatic thermal regulator of claim 1, wherein the downstream channel portion includes at least one of a converging portion and a diverging portion.

5. The adiabatic thermal regulator of claim 1, wherein:
the stage comprises a plurality of expansion chambers defined along portions of the passageway; and
for each expansion chamber of the plurality of expansion chambers:
at least one upstream channel portion is in communication with each expansion chamber, and is positioned upstream of the respective expansion chamber; and
at least one downstream channel portion is in communication with each expansion chamber, and is positioned downstream of the respective expansion chamber.

6. The adiabatic thermal regulator of claim 1, further comprising a plurality of stages defined along the length of the passageway and in communication with each other, wherein each stage of the plurality of stages is configured to cause a gas flowing therethrough to undergo compression and expansion as the gas flows through the stage, such that a temperature of the gas is modified via adiabatic or near-adiabatic processes.

7. The adiabatic thermal regulator of claim 6, wherein each stage of the plurality of stages comprises:
at least one expansion chamber defined along a portion of the passageway;
an upstream channel portion in communication with the at least one expansion chamber, and defined along a portion of the passageway upstream of the at least one expansion chamber; and
a downstream channel portion in communication with the at least one expansion chamber, and defined along a portion of the passageway downstream of the at least one expansion chamber.

8. The adiabatic thermal regulator of claim 7, wherein:
the upstream channel portion of each stage is in communication with a downstream channel portion of an upstream stage or with a portion of the passageway in communication with the upstream end of the body; and
the downstream channel portion of each stage is in communication with an upstream channel portion of a downstream stage or with a portion of the passageway in communication with the downstream end of the body.

9. The adiabatic thermal regulator of claim 6, wherein:
at least one stage of the plurality of stages comprises a plurality of expansion chambers defined along portions of the passageway; and
for each expansion chamber of the plurality of expansion chambers:
at least one upstream channel portion is in communication with each expansion chamber, and is positioned upstream of the respective expansion chamber; and
at least one downstream channel portion is in communication with each expansion chamber, and is positioned downstream of the respective expansion chamber.

10. The adiabatic thermal regulator of claim 1, further comprising a plurality of non-intersecting internal passageways, each passageway being in communication with at least one environment external to the body at the upstream end and at the downstream end.

11. A method of regulating a temperature of a gas using an adiabatic thermal regulator, the adiabatic thermal regulator comprising a body having an internal passageway and at least one stage defined along a length of the passageway, the stage including at least one expansion chamber and channel portions positioned upstream and downstream of the expansion chamber, the method comprising:
introducing gas into the passageway at an upstream end of the body;
flowing the gas through the stage;
modifying a temperature of the gas via adiabatic or near-adiabatic compression and expansion as it flows through the stage; and
receiving the gas from the passageway at a downstream end of the body;
wherein the step of flowing the gas through the stage further comprises:
compressing the gas through the channel portion positioned upstream of the expansion chamber;
expanding the gas by flowing the gas into the expansion chamber; and
flowing the gas through the channel portion positioned downstream of the expansion chamber.

12. The method of claim 11, wherein flowing the gas through the channel portion positioned downstream of the expansion chamber further comprises compressing the gas.

13. The method of claim 11, further comprising flowing the gas through a plurality of stages and modifying the temperature of the gas via adiabatic or near-adiabatic compression and expansion as it flows through each stage.

14. The method of claim 11, wherein the temperature of the gas is modified without heat exchange.

15. A method of designing an adiabatic thermal regulator, the adiabatic thermal regulator comprising a body defining an internal passageway and at least one stage defined along a length of the passageway, each stage including at least one expansion chamber and channel portions positioned upstream and downstream of the expansion chamber, the method comprising:
selecting a desired thermal effect to be imparted to a gas flowing through the passageway;
determining a number of stages to be defined along the passageway based on the desired thermal effect;
for each stage, selecting a volume of the expansion chamber;
for each stage, selecting geometries of channel portions positioned upstream and downstream of the expansion chamber relative to the selected volume of the expansion chamber; and
configuring the expansion chamber and channel portions such that gas flowing through the stage undergoes compression and expansion under adiabatic or near-adiabatic conditions.

16. The method of claim 15, wherein selecting the volume of the expansion chamber and selecting geometries of the channel portions comprise selecting the volume and geometries to control a rate at which gas charges and discharges the expansion chamber during operation.

17. The method of claim 16, wherein selecting the volume of the expansion chamber and selecting geometries of the channel portions comprise selecting the volume and geometries to correspond to a characteristic dynamic response of the gas flowing through the stage.

18. The method of claim 17, wherein selecting the volume of the expansion chamber and selecting geometries of the channel portions comprise selecting the volume and geometries according to a geometric relationship between chamber volume and an effective geometry of an associated channel, the geometric relationship being selected to support the characteristic dynamic response of the gas.

19. The method of claim 15, further comprising determining a desired mass flow rate of the gas, wherein selecting the volume of the expansion chamber and selecting geometries of the channel portions comprise selecting the volume and geometries to accommodate the desired mass flow rate.

20. The method of claim 15, wherein determining the number of stages and selecting the volume of the expansion chamber for each stage comprise selecting the number of stages and chamber volumes according to a set of geometric relationships that relate internal chamber volumes and connecting channel geometries to desired gas-flow dynamics and thermal output.
